(19) United States
(12) Patent Application Publication
(10) Pub. No.: US 2021/0193866 A1
(43) Pub. Date: Jun. 24, 2021

(54) METHOD OF FORMING DISPLAY DEVICE WITH LIGHT-EMITTING DIODE

(71) Applicant: MIKRO MESA TECHNOLOGY CO., LTD., Apia (WS)

(72) Inventor: Li-Yi CHEN, Tainan City (TW)

(21) Appl. No.: 16/726,273

(22) Filed: Dec. 24, 2019

(51) Int. Cl. H01L 33/00

(52) U.S. Cl. CPC H01L 33/0095; H01L 2933/0066; H01L 2933/0016

(57) ABSTRACT

A method includes preparing a substrate with a first and a second conductive pad thereon; bonding a light-emitting diode to the first conductive pad; forming a photoresist layer on the substrate such that a difference between a thickness of a portion of the photoresist layer overlying the light-emitting diode and a thickness of another portion of the photoresist layer free from overlapping with the light-emitting diode and the second conductive pad is greater than a distance from an interface between the second type semiconductor layer and the active layer to a top surface of the substrate; respectively exposing a first and a second exposure region of the photoresist layer with a first and a second exposure dose; and developing the exposed photoresist layer till the top surface of the second type semiconductor layer and a top surface of the second conductive pad are exposed from the photoresist layer.

### BACKGROUND

### Field of Invention

The present disclosure relates to a method of forming a display device with a light-emitting diode.

### Description of Related Art

The statements in this section merely provide background information related to the present disclosure and do not necessarily constitute prior art.

Traditional display manufacturing is a standardized process set. In recent years, there are more and more new types of displays such as a micro light-emitting diode display, a mini light-emitting diode display, and a quantum dot light-emitting diode display . . . etc., which are promising to dominate the future display market, and thus new display manufacturing processes are waiting to be set up. There are many steps contained in a manufacturing process set in order to produce one display, and reducing one of the steps thereof can reduce the cost and enhance the efficiency.

### SUMMARY

According to some embodiments of the present disclosure, a method of forming a display device with a light-emitting diode is provided. The method includes: preparing a substrate having a top surface with a first conductive pad and a second conductive pad thereon; bonding a light-emitting diode to the first conductive pad, the light-emitting diode comprising a bottom electrode, a first type semiconductor layer on the bottom electrode, an active layer on the first type semiconductor layer, and a second type semiconductor layer on the active layer, in which the bottom electrode is in contact with the first conductive pad when the light-emitting diode is bonded to the first conductive pad; forming a photoresist layer on the substrate to cover the top surface of the substrate, the first conductive pad, the second conductive pad, and the light-emitting diode such that a difference between a thickness of a portion of the photoresist layer overlying the light-emitting diode and a thickness of another portion of the photoresist layer free from overlapping with the light-emitting diode and the second conductive pad is greater than a distance from an interface between the second type semiconductor layer and the active layer to the top surface of the substrate; exposing a first exposure region of the photoresist layer with a first exposure dose and a second exposure region of the photoresist layer with a second exposure dose, in which a vertical projection of the first exposure region on the substrate is spaced apart from a vertical projection of the second conductive pad on the substrate, and a vertical projection of the second exposure region on the substrate is overlapped with the vertical projection of the second conductive pad on the substrate; and developing the exposed photoresist layer till the top surface of the second type semiconductor layer of the light-emitting diode and a top surface of the second conductive pad are exposed from the photoresist layer.

### BRIEF DESCRIPTION OF THE DRAWINGS

The disclosure can be more fully understood by reading the following detailed description of the embodiment, with reference made to the accompanying drawings as follows:

FIG. 1 is a flow chart of a method of forming electrical connection of a light-emitting diode;

FIGS. 2A to 2F are schematic cross-sectional views of intermediate stages of the method of FIG. 1 according to some embodiments of the present disclosure; and

FIG. 2G is a schematic cross-sectional view of an intermediate stage of the method of FIG. 1 according to other embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In various embodiments, the description is made with reference to figures. However, certain embodiments may be practiced without one or more of these specific details, or in combination with other known methods and configurations. In the following description, numerous specific details are set forth, such as specific configurations, dimensions, and processes, etc., in order to provide a thorough understanding of the present disclosure. In other instances, well-known semiconductor processes and manufacturing techniques have not been described in particular detail in order to not unnecessarily obscure the present disclosure. Reference throughout this specification to “one embodiment,” “an embodiment” or the like means that a particular feature, structure, configuration, or characteristic described in connection with the embodiment is included in at least one embodiment of the disclosure. Thus, the appearances of the phrase “in one embodiment,” “in an embodiment” or the like in various places throughout this specification are not necessarily referring to the same embodiment of the disclosure. Furthermore, the particular features, structures, configurations, or characteristics may be combined in any suitable manner in one or more embodiments.

The terms “over,” “to,” “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

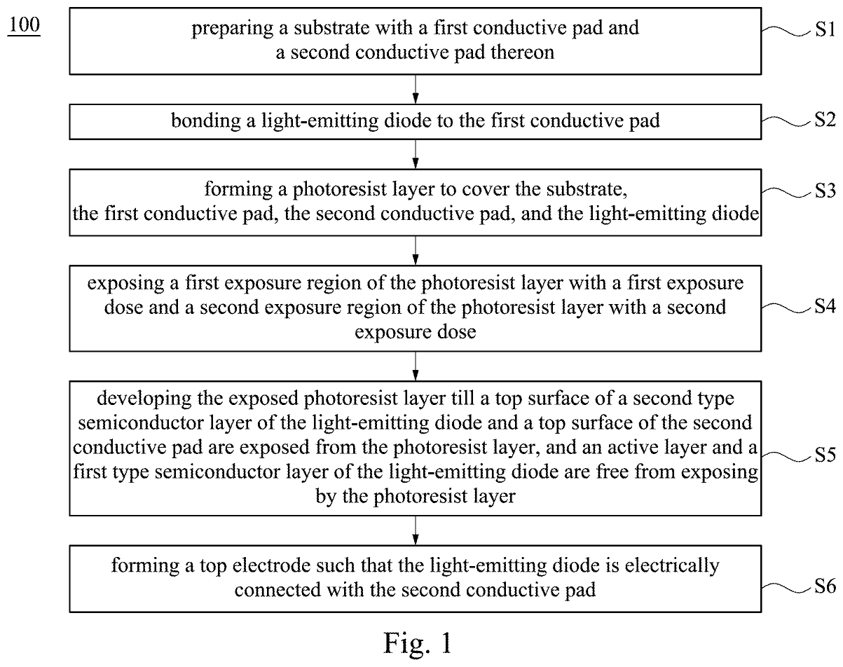

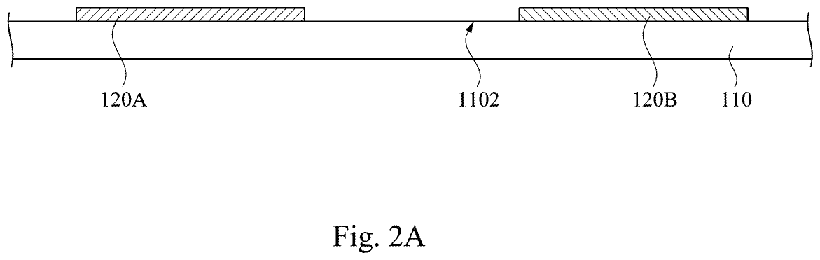

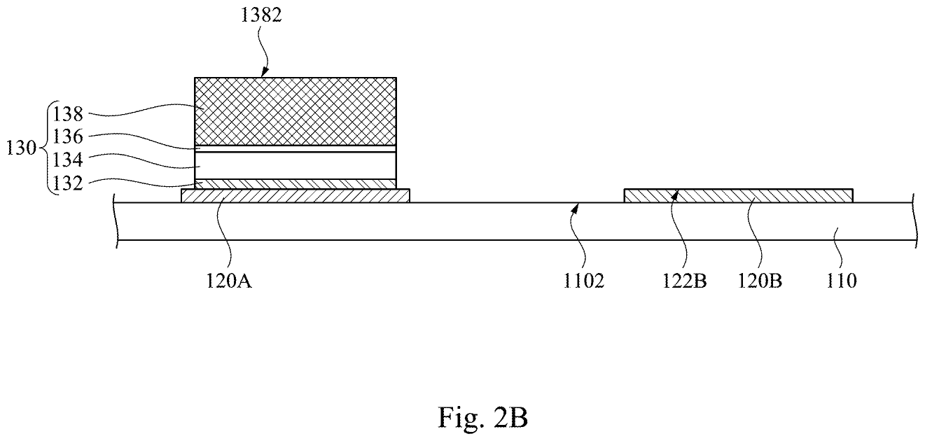

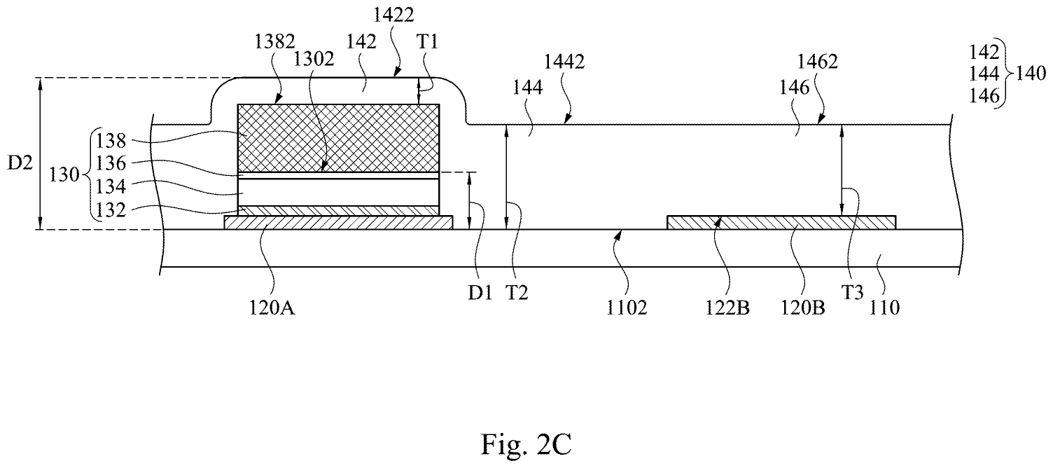

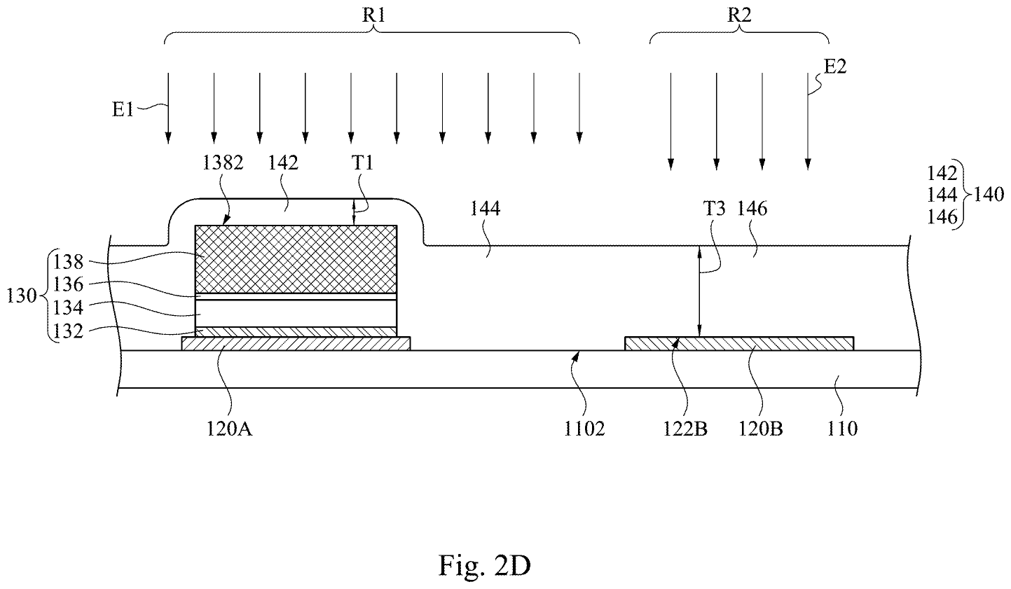

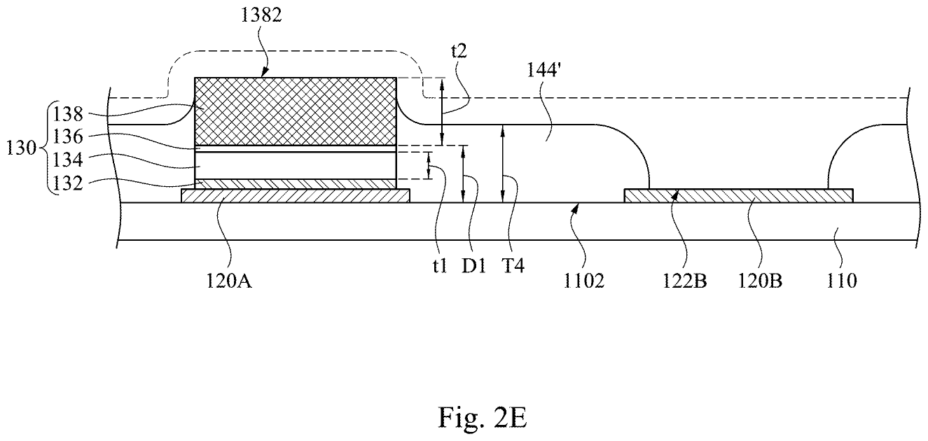

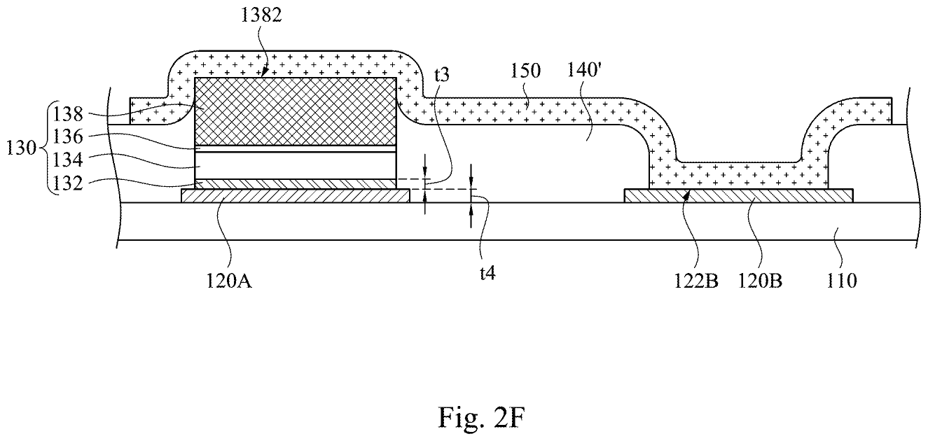

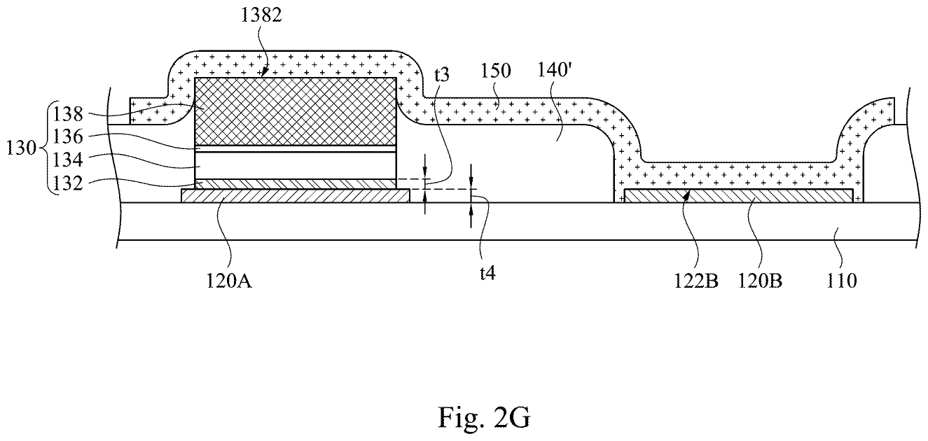

FIG. 1 is a flow chart of a method 100 of forming electrical connection of a light-emitting diode. FIGS. 2A to 2F are schematic cross-sectional views of intermediate stages of the method 100 of FIG. 1 according to some embodiments of the present disclosure. Reference is made to FIG. 1 and FIG. 2A. The method 100 of forming electrical connection of a light-emitting diode begins with step S1 in which a substrate 110 with a first conductive pad 120A and a second conductive pad 1208 thereon is prepared. The substrate 110 has a top surface 1102. The first conductive pad 120A and the second conductive pad 120B are formed on the top surface 1102 of the substrate 110.

Reference is made to FIG. 1 and FIG. 2B. The method 100 continues with step S2 in which a light-emitting diode 130 is bonded to the first conductive pad 120A. The light-emitting diode 130 includes a bottom electrode 132, a first type semiconductor layer 134, an active layer 136, and a second type semiconductor layer 138. The first type semiconductor layer 134 is on the bottom electrode 132. The active layer 136 is on the first type semiconductor layer 134. The second type semiconductor layer 138 is on the active layer 136. The bottom electrode 132 is in contact with the first conductive pad 120A when the light-emitting diode 130 is bonded to the first conductive pad 120A. In the present embodiment, the light-emitting diode 130 is a vertical type light-emitting diode.

In some embodiments, the first type semiconductor layer 134 is a p-type semiconductor layer, and the second type semiconductor layer 138 is an n-type semiconductor layer. Under this condition, the thicker layer is the n-type semiconductor layer which has lower resistivity compared to the p-type semiconductor layer, which leads to better light-emitting efficiency because the p-type semiconductor layer which has higher resistivity and contact resistance is already fully in contact with the bottom electrode 132 before the light-emitting diode 130 is bonded to the conductive pad 120. In some embodiments, a thickness of the p-type semiconductor layer is about 250 nm and a thickness of the active layer 136 is about 150 nm. In some embodiments, the light-emitting diode 130 further includes an electron blocking layer (not shown) between the active layer 136 and the p-type semiconductor layer 134 so as to prevent electrons (which flow from the n-type semiconductor layer towards the active layer 136) from flowing out of the active layer 136 (and into the p-type semiconductor layer) and thus the light-emitting efficiency is enhanced.

Reference is made to FIG. 1 and FIG. 2C. The method 100 continues with step S3 in which a photoresist layer 140 is formed on the substrate 110 to cover the top surface 1102 of the substrate 110, the first conductive pad 120A, the second conductive pad 120B, and the light-emitting diode 130. The photoresist layer 140 covers a top surface 1382 of the second type semiconductor layer 138 and a top surface 122B of the second conductive pad 120B. Specifically, a first portion 142 of the photoresist layer 140 overlying the light-emitting diode 130 has a thickness T1. A second portion 144 of the photoresist layer 140 free from overlapping with the light-emitting diode 130 and the second conductive pad 1206 has a thickness T2. A third portion 146 of the photoresist layer 140 overlying the second conductive pad 1206 has a thickness T3. The thickness T2 and the thickness T3 are greater than the thickness T1, and the thickness T3 may be close to the thickness T2.

The first portion 142 of the photoresist layer 140 has a first surface 1422, and a vertical projection of the first surface 1422 projected on the substrate 110 is overlapped with a vertical projection of the light-emitting diode 130 projected on the substrate 110. The thickness T1 is equal to the distance from the first surface 1422 to the top surface 1382 of the second type semiconductor layer 138. The second portion 144 of the photoresist layer 140 has a second surface 1442, and a vertical projection of the second surface 1442 projected on the substrate 110 is spaced apart from vertical projections of the light-emitting diode 130 and the second conductive pad 1206 projected on the substrate 110. The thickness T2 is equal to the distance from the second surface 1442 to the top surface 1102 of the substrate 110. The third portion 146 of the photoresist layer 140 has a third surface 1462, and a vertical projection of the third surface 1462 projected on the substrate 110 is overlapped with a vertical projection of the second conductive pad 120B projected on the substrate 110. The thickness T3 is equal to the distance from the third surface 1462 to the top surface 122B of the second conductive pad 120B. In addition, a difference between the thickness T2 and the thickness T3 is smaller than a difference between the thickness T2 and the thickness T1.

Reference is made to FIG. 1 and FIG. 2D. A material of the photoresist layer 140 is positive photoresist. The method 100 continues with step S4 in which a first exposure region R1 of the photoresist layer 140 is exposed with a first exposure dose E1 and a second exposure region R2 of the photoresist layer 140 is exposed with a second exposure dose E2 greater than the first exposure dose E1. A vertical projection of the first exposure region R1 on the substrate 110 is at least overlapped with the light-emitting diode 130 but is spaced apart from a vertical projection of the second conductive pad 120B on the substrate 110. A vertical projection of the second exposure region R2 on the substrate 110 is overlapped with the vertical projection of the second conductive pad 120B on the substrate 110, and the vertical projection of the second exposure region R2 may be smaller than the vertical projection of the second conductive pad 120B on the substrate 110. In other words, the first exposure region R1 corresponds to the first portion 142 and the second portion 144 of the photoresist layer 140, and the second exposure region R2 corresponds to the third portion 146 of the photoresist layer 140. In some embodiments, the photoresist layer 140 may be exposed by UV light, but the present disclosure is not limited in this regard. In some embodiments, the photoresist layer 140 includes high reflective index nanoparticles (e.g., titanium oxide (TiO₂) nanoparticles or zirconium oxide (ZrO₂) nanoparticles) to increase a refractive index of the photoresist layer 140 to further enhance the light extraction efficiency.

Reference is made to FIG. 1, FIG. 2D, and FIG. 2E. The method 100 continues with step S5 in which the exposed photoresist layer 140 is developed till the top surface 1382 of the second type semiconductor layer 138 of the light-emitting diode 130 and the top surface 122B of the second conductive pad 120B are exposed from the photoresist layer 140. In other words, since the third portion 146 is thicker than the first portion 142 and the second exposure dose E2 is greater than the second exposure dose E2, the first portion 142 and the third portion 146 of the photoresist layer 140 which includes the photo-sensitive material are all degraded and the top surface 1382 of the second type semiconductor layer 138 of the light-emitting diode 130 and the top surface 122B of the second conductive pad 120B can be exposed from the photoresist layer 140 with one exposing process and one developing process. As a result, the step in conventional manufacturing process that forming a mask for patterning an opening in the photoresist layer 140 to expose the second conductive pad 120B after the second type semiconductor layer 138 is already exposed from the photoresist layer 140 can be omitted. Therefore, the manufacturing cost can be reduced and the manufacturing efficiency can be enhanced.

Reference is made to FIG. 2C and FIG. 2E. A difference between the thickness T1 and the thickness T2 is greater than a distance D1 from an interface 1302 between the active layer 136 and the second type semiconductor layer 138 to the top surface 1102 of the substrate 110. In other words, the configurations of the photoresist layer 140 and the light-emitting diode 130 satisfy the relation: T2−T1>D1. In addition, a distance D2 from the first surface 1422 of the photoresist layer 140 to the top surface 1102 of the substrate 110 is greater than the thickness T2 of the second portion 144 of the photoresist layer 140. As such, after the developing process (i.e., the step S5), the top surface 1382 of the second type semiconductor layer 138 is higher than the top surface of the remaining second portion 144′ so as to be exposed from the photoresist layer 140. Therefore, since the remaining second portion 144′ still covers the first type semiconductor layer 134 and the active layer 136, the electrical insulation between the first type semiconductor layer 134 and the second type semiconductor layer 138 can be maintained. In some embodiments, the photoresist layer 140 is formed by spin coating or slit coating so as to form the configuration of the photoresist layer 140 and satisfy the relation: T2−T1>D1 in one coating step.

In some embodiments, the exposing the photoresist layer 140 (i.e., the step S4) is performed through a mask. The mask may have transmission regions, half transmission regions, and/or non-transmission regions. In one embodiment, the mask may be a gray-tone mask, and the half transmission regions of the gray-tone mask regions have features (e.g., slits) that are not resolvable for the exposure system. In another embodiment, the mask may be a half-tone mask, and the half transmission regions of the half-tone mask may have translucent film (i.e., partial transmission layer or a metal film with a thinner coating). Therefore, the normalized intensity of the light passes through the half transmission regions of the mask will be lower than the intensity of the light passes through the transmission regions of the mask. For example, the first exposure region R1 may correspond to the half transmission region of the mask such that the first exposure does E1 is about 5% of the intensity of a light source so as to ensure that the second portion 144 of the photoresist layer 140 which includes a photo-sensitive material is only partially degraded. The second exposure region R2 may correspond to the transmission region of the mask such that the second exposure does E2 is 100% of the intensity of the light source so as to ensure that the top surface 122B of the second conductive pad 120B can be exposed from the photoresist layer 140.

In some other embodiments, the exposing the photoresist layer 140 may be performed by weakly exposing the entire top surface of the photoresist layer 140 without using a mask first, and then the second exposure region R2 may be further exposed by using a mask so as to ensure that the top surface 1228 of the second conductive pad 120B can be exposed from the photoresist layer 140 after the developing process.

In some embodiments, the first exposure dose E1 and the second exposure dose E2 are respectively determined through a first exposure time duration and a second exposure time duration different from the first exposure time duration. The exposure time durations are modulated by a DMD (Digital micro-mirror device) module having a micro mirror array. Tilt angle of each mirror of the micro mirror array is individually controlled to be in “on state” (reflect light from the light source to the photoresist layer 140) or “off state” (without reflecting the light from the light source to the photoresist layer 140). During the exposing process, the mirror is switched on and off quickly, and the ratio of the time in “on state” to the time in “off state” determines the exposure time durations. For example, if the exposing process lasts for 1 second, and the first exposure region R1 may be exposed with a first exposure time duration of 0.7 second while the second exposure region R2 may be exposed with a second exposure time duration of 1 second such that the second exposure dose E2 would be greater than the first exposure dose E1.

In some other embodiments, the exposing the photoresist layer 140 (i.e., the step S4) is performed through a laser scanning process. The laser light may scan through the photoresist layer 140 with different pulse numbers at different regions. For example, the first exposure region R1 may be scanned with a first pulse number and the second exposure region R2 may be scanned with a second pulse number that is greater than the first pulse number such that the second exposure dose E2 is greater than the first exposure dose E1.

Reference is made to FIG. 2D and FIG. 2E. In some embodiments, a ratio between a thickness t2 of the second type semiconductor layer 138 and a thickness t1 of the first type semiconductor layer 134 is greater than or equal to about 1.5. When the second type semiconductor layer 138 is thicker than the first type semiconductor layer 134, there is a higher possibility for a thickness T4 of the remaining second portion 144′ to be greater than the distance D1 from the interface 1302 between the active layer 136 and the second type semiconductor layer 138 to the top surface 1102 of the substrate 110. Therefore, the thickness relation between the second type semiconductor layer 138 and the first type semiconductor layer 134 can increase the tolerance of the criterion: T2−T1>D1 as mentioned above in the step S3. In some embodiments, since the largest possible distance D1 is equal to or smaller than about 2 μm, the thickness T4 of the remaining second portion 144′ of the photoresist layer 140 is greater than or equal to about 2 μm such that the electrical insulation between the first type semiconductor layer 134 and the second type semiconductor layer 138 can be better maintained.

In some other embodiments, the region of the photoresist layer 140 of which a vertical projection on the substrate 110 is free from overlapping with the second conductive pad 1206 and the light-emitting diode 130 may be exposed with another exposure dose that is greater than 0 and smaller than the first exposure dose E1. Under this condition, the first exposure region R1 corresponds to the first portion 142. The second portion 144 of the photoresist layer 140 after developing process may have a thickness greater than the thickness T4. Therefore, the electrical insulation between the first type semiconductor layer 134 and the second type semiconductor layer 138 can be maintained.

Reference is made to FIG. 1 and FIG. 2F. The method 100 continues with step S6 in which a top electrode 150 is formed to be in contact with the top surface 1382 of the second type semiconductor layer 138 of the light-emitting diode 130 and the top surface 122B of the second conductive pad 120B such that the light-emitting diode 130 is electrically connected with the second conductive pad 120B. Since the top surface 1382 of the second type semiconductor layer 138 and the top surface 122B of the second conductive pad 120B are exposed from the photoresist layer 140 while the active layer 136 and the first type semiconductor layer 134 of the light-emitting diode 130 are still covered by the photoresist layer 140, the top electrode 150 can be directly formed to cover the second type semiconductor layer 138, the second conductive pad 120B, and the remaining photoresist layer 140′. In some embodiments, the top electrode 150 is transparent so that light emitted from the light-emitting diode 130 can transmit through the top electrode 150 to enhance light extraction efficiency.

Reference is made to FIG. 2G. FIG. 2G is a schematic cross-sectional view of an intermediate stage of the method of FIG. 1 according to other embodiments of the present disclosure. In the present embodiment, the entire top surface 122B of the second conductive pad 120B is exposed from the photoresist layer 140′. The top electrode 150 may be in contact with the entire top surface 122B of the second conductive pad 120B. In some embodiments, the top electrode 150 may be at least partially in contact with the substrate 110.

Furthermore, in some embodiments, in case the light-emitting diode 130 is absent on the first conductive pad 120A due to defects when the light-emitting diodes 130 are massively transferred to the substrate 110, a portion of the photoresist layer 140 overlying the first conductive pad 120A will be thicker by using the photoresist layer 140 forming process as described in the step S3.

For example, the portion of the photoresist layer 140 overlying the first conductive pad 120A may be as thick as the third portion 146, and the first conductive pad 120A can still be covered by the remaining photoresist layer 140 after the developing process. Therefore, the electrical insulation between the top electrode 150 and the first conductive pad 120A can be maintained, thereby preventing the electrical short that may occur in conventional manufacturing process.

In some embodiments, the light-emitting diode 130 is a micro light-emitting diode having a lateral length less than or equal to about 100 μm. It is further noted that a preferable condition for a sum of a thickness t3 of the bottom electrode 132 and a thickness t4 of the first conductive pad 120A is smaller than or equal to about 2 μm. The 2 μm is a balance of size (i.e., the lateral length about 100 μm) of the micro light-emitting diode and a capability to have an interstitial diffusion between the bottom electrode 132 and the first conductive pad 120A when the micro light-emitting diode is bonded to the first conductive pad 120A. As a result, no melting process is performed during the bonding, and the micro light-emitting diode is better protected from damaging during bonding and a position of the micro light-emitting diode relative to the first conductive pad 120A can be better controlled.

Due to the tiny size of the micro light-emitting diode, the alignment between the micro light-emitting diode and an opening for exposing the second type semiconductor layer of the micro light-emitting diode in a conventional manufacturing method may become more challenging. Therefore, the step S4 of the method 100 that exposing the second type semiconductor layer of the micro light-emitting diode and the second conductive pad can replace the step of forming the opening for exposing the top surface of the second type semiconductor layer, thereby preventing the electrical short due to the misalignment between the said opening and the micro light-emitting diode. Furthermore, in the conventional manufacturing method, it is more difficult to form the top electrode 150 in the opening (i.e., contact hole) with a smaller size. Therefore, the method 100 of the present disclosure can omit the step of forming the top electrode 150 in openings that expose the second type semiconductor layer and the second conductive pad 120B, thereby improving the electrical connection quality. Accordingly, the design rule for forming a display device with a micro light-emitting diode can be achieved easier, or the pitch can even be shrink, thereby preventing the misalignment problem and improving the electrical connection quality.

In summary, the method of forming a display device with a light-emitting diode of the present disclosure is able to expose the top surface of the second type semiconductor layer of the light-emitting diode and the second conductive pad in one step. At least one step in conventional manufacturing process that forming a mask for pattern an opening to exposing the second conductive pad after the second type semiconductor layer is already exposed from the photoresist layer can be omitted. Therefore, the manufacturing cost can be reduced and the manufacturing efficiency can be enhanced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the method and the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of forming a display device with a light-emitting diode, comprising:
preparing a substrate having a top surface with a first conductive pad and a second conductive pad thereon;
bonding a light-emitting diode to the first conductive pad, the light-emitting diode comprising a bottom electrode, a first type semiconductor layer on the bottom electrode, an active layer on the first type semiconductor layer, and a second type semiconductor layer on the active layer, wherein the bottom electrode is in contact with the first conductive pad when the light-emitting diode is bonded to the first conductive pad;
forming a photoresist layer on the substrate to cover the top surface of the substrate, the first conductive pad, the second conductive pad, and the light-emitting diode such that a difference between a thickness of a portion of the photoresist layer overlying the light-emitting diode and a thickness of another portion of the photoresist layer free from overlapping with the light-emitting diode and the second conductive pad is greater than a distance from an interface between the second type semiconductor layer and the active layer to the top surface of the substrate;
exposing a first exposure region of the photoresist layer with a first exposure dose and a second exposure region of the photoresist layer with a second exposure dose, wherein a vertical projection of the first exposure region on the substrate is spaced apart from a vertical projection of the second conductive pad on the substrate, and a vertical projection of the second exposure region on the substrate is overlapped with the vertical projection of the second conductive pad on the substrate; and
developing the exposed photoresist layer till a top surface of the second type semiconductor layer of the light-emitting diode and a top surface of the second conductive pad are exposed from the photoresist layer.

2. The method of claim 1, wherein exposing the photoresist layer is performed through a mask.

3. The method of claim 1, wherein the first exposure dose and the second exposure dose are respectively determined by a first exposure time duration and a second exposure time duration different from the first exposure time duration.

4. The method of claim 1, wherein the first exposure dose and the second exposure dose are respectively determined by a first laser pulse number and a second laser pulse number different from the first laser pulse number during a laser scanning process.

5. The method of claim 1, further comprising:
forming a top electrode to be in contact with the top surface of the second type semiconductor layer of the light-emitting diode and the top surface of the second conductive pad such that the light-emitting diode is electrically connected with the second conductive pad.

6. The method of claim 5, wherein the top electrode is transparent.

7. The method of claim 1, wherein a material of the photoresist layer is positive photoresist, and the second exposure dose is greater than the first exposure dose.

8. The method of claim 1, wherein the photoresist layer is formed by spin coating or slit coating.

9. The method of claim 1, wherein a thickness of a portion of the photoresist layer overlying the second conductive pad is greater than the thickness of the portion of the photoresist layer overlying the light-emitting diode.

10. The method of claim 1, wherein a ratio between a thickness of the second type semiconductor layer and a thickness of the first type semiconductor layer is greater than or equal to about 1.5.

11. The method of claim 10, wherein the first type semiconductor layer is a p-type semiconductor layer, and the second type semiconductor layer is an n-type semiconductor layer.

12. The method of claim 1, wherein the photoresist layer comprises high reflective index nanoparticle.

13. The method of claim 1, wherein a sum of a thickness of the bottom electrode and a thickness of the first conductive pad is smaller than or equal to about 2 μm.

14. The method of claim 1, wherein a thickness of the photoresist layer after said developing is greater than or equal to about 2 μm.
